(19) United States
(12) Patent Application Publication
(10) Pub. No.: US 2016/0276242 A1
(43) Pub. Date: Sep. 22, 2016

(54) THERMAL SPREADER HAVING INTER-METAL DIFFUSION BARRIER LAYER

(71) Applicant: Raytheon Company, Waltham, MA (US)

(72) Inventor: Susan C. Trulli, Lexington, MA (US)

(73) Assignee: Raytheon Company, Waltham, MA (US)

(21) Appl. No.: 14/664,310

(22) Filed: Mar. 20, 2015

(51) Int. Cl. H01L 23/34; F28F 21/08

(52) U.S. Cl. CPC H01L 23/34; F28F 21/085; F28F 21/087; F28F 21/089

(57) ABSTRACT

A heat spreader provided having: as ceramic substrate; and metallization layer structure disposed on at least one surface of the substrate. The metallization layer structure includes: a thick film layer disposed on the at least one surface of the substrate; a diffusion barrier layer on, and in direct contact with the thick film layer; and as heat conducting layer disposed on, and in direct contact with, the diffusion barrier layer. The diffusion barrier layer inhibits material in the thick film layer and material in the heat conducting layer from diffusing between the thick film layer and the heat conductive layer. The metallization layer structure is disposed on a plurality of sides of the substrate.

### TECHNICAL FIELD

This disclosure relates generally to thermal heat spreaders and more particularly to heat spreaders for high power dissipating semiconductor devices.

### BACKGROUND AND SUMMARY

As is known in the art, heat spreaders are used to spread heat generated from a heat source, such as heat generated in an electrical circuit, and then thermally conduct the spread heat to a heat sink. As is also known in the art, in order to meet cost and performance goals, Monolithic Microwave Integrated Circuit (MMIC) devices are moving away from coplanar waveguide (CPW) designs to microstrip designs, allowing for higher wafer packing densities exacerbating the need for a high performance thermal stack. The MMIC devices having for example Gallium Nitride (GaN) epitaxial layer on a silicon carbide (SiC) substrate, for example, is processed by sometimes being thinned from 500 micron substrate to 100 or 50 micron substrate thickness depending on the process and frequency requirement. This thinning unfortunately diminishes heat spreading within the device so the requirement of enhanced heat spreaders to remove the heat from the device becomes greater as the device is thinned. Additionally, spreaders allow for re-workability, as well as thermal management, at the next level of assembly.

Current standard heat spreaders for high power microwave GaN devices are Molybdenum (Mo) or Molybdenum Copper (MoCu) or in extreme thermal situations, diamond. Emerging materials include aluminum diamond, silver diamond and copper diamond. These emerging materials are either risky or costly or both.

Another material suggested for a CPW heat spreader is Beryllium Oxide (BeO), as shown in FIG. 1. Here, the bottom of the SiC substrate is soldered to the top of a BeO heat spreader with a gold tin (AuSu) solder, not shown. The bottom of the BeO heat spreader is then epoxied to MoCu base or heat sink, as indicated. In order to enhance the solderability to the SiC substrate, a tri-layer metallization is used. More particularly, a layer of thick film silver (Ag) for adhesion to the BeO is fired onto the BeO followed by the tri-layer plated metal consisting of copper (Cu) plated on the surface of the thick film silver. As is known, a thick film process is an additive process whereby conductor, resistive of dielectric pastes are screen printed, stenciled or dispensed onto an insulating substrate and subsequently fired, typically by a sequential process. The tri-layer plated metal consisting of copper (Cu) plated on the surface of the thick film silver is followed by plating a layer of nickel (Ni) over the to Cu using, for example, a Remtec PTCF® (plated copper on thick film) process. However, the inventor has recognized that this technique falls short, however in high power applications. More particularly, the inventor has recognized that this tri-layer metallization scheme fails at extended time at 150° C. and higher as inter-diffusion between the plated copper and thick film silver eventually depletes the metal in the thick film silver causing the is metallization to delaminate or “unzip” (peel) from the BeO.

The inventor has also recognized the need for a mature technology using thick film metallization on BeO with wrap around grounds. As noted above, a diffusion barrier is added to the tri-metal scheme between the thick film Ag and the Cu. Many different materials can be used as the diffusion barrier. In one embodiment nickel is used to uniformly cover all thick film surfaces on the BeO. Thick upper is then plated on the diffusion barrier for excellent electrical grounding and to aid in heat spreading. This can also be applied to other dielectric substrates such as alumina or aluminum nitride.

More particularly, by adding a diffusion barrier over thick film, a mature, low risk thick film and plate up process on BeO can be used to provide heat spreading at much lower cost and risk than other high conductivity heat spreaders.

In accordance with the present disclosure, a heat spreader is provided having: a substrate; and metallization layer structure disposed on at least one surface of the substrate. The metallization layer structure includes: a thick film layer disposed on the at least one surface of the substrate; a diffusion barrier layer on, and in direct contact with the thick film layer; and a heat conducting layer disposed on, and in direct contact with, the diffusion barrier layer. The diffusion barrier layer inhibits material in the thick film layer and material in the heat conducting layer from diffusing between the thick film layer and the heat conductive layer.

In one embodiment, the substrate is a ceramic substrate.

In one embodiment, the thick film layer comprises silver and wherein the diffusion barrier layer inhibits silver in the thick film layer and the material in the heat conducting layer from diffusing between the thick film layer and the heat conductive layer.

In one embodiment, the heat conductive layer comprises copper and wherein the diffusion barrier layer inhibits material in the thick film layer and the copper in the heat conducting layer from diffusing between the thick film layer and the heat conductive layer.

In one embodiment, the thick film layer comprises silver and wherein the diffusion barrier layer inhibits silver in the thick film layer and the copper in the heat conducting layer from diffusing between the thick film layer and the heat conductive layer.

In one embodiment, the metallization layer structure is disposed on at least one side of the substrate.

In one embodiment, the at least one surface is a horizontal surface;

In one embodiment, the metallization layer structure is disposed on a horizontal surface and at least one vertical side of the substrate.

In one embodiment, the metallization layer structure is disposed on a horizontal surface and a plurality of vertical sides of the substrate. In one embodiment, the metallization layer structure is disposed on top and bottom surface of the substrate.

In one embodiment, a heat spreader is provided, having: a ceramic substrate; and a metallization layer structure disposed on a plurality of sides of the substrate.

In one embodiment, the ceramic is BeO.

In one embodiment, a heat spreader is provided having a ceramic substrate; and a metallization layer structure disposed on a plurality of sides of the substrate.

In one embodiment, the metallization layer is on a horizontal surface of the substrate and the sides are vertical sides of the substrate.

In one embodiment, the metallization layer structure is disposed on top, bottom, and at least one side of the substrate.

By forming a metallization layer on the top bottom and at least one side of the substrate, high power microwave MMIC device applications will benefit from the full edge wrap from the top, side and bottom of the substrate electrically as well as thermally.

The details of one or more embodiments of the disclosure are set forth in the accompanying drawings and the description below. Other features, objects, and advantages of the disclosure will be apparent from the description and drawings, and from the claims.

### DESCRIPTION OF DRAWINGS

FIG. 1 is a cross sectional view of a heat spreader disposed between a heat source and a heat sink according to the PRIOR ART;

FIG. 2 is a top view of a heat spreader according to the disclosure; and

FIGS. 3 and 4 is a cross sectional view of the heat spreader of according to another embodiment of the disclosure, the cross section being taken along line 3-3 of FIG. 4.

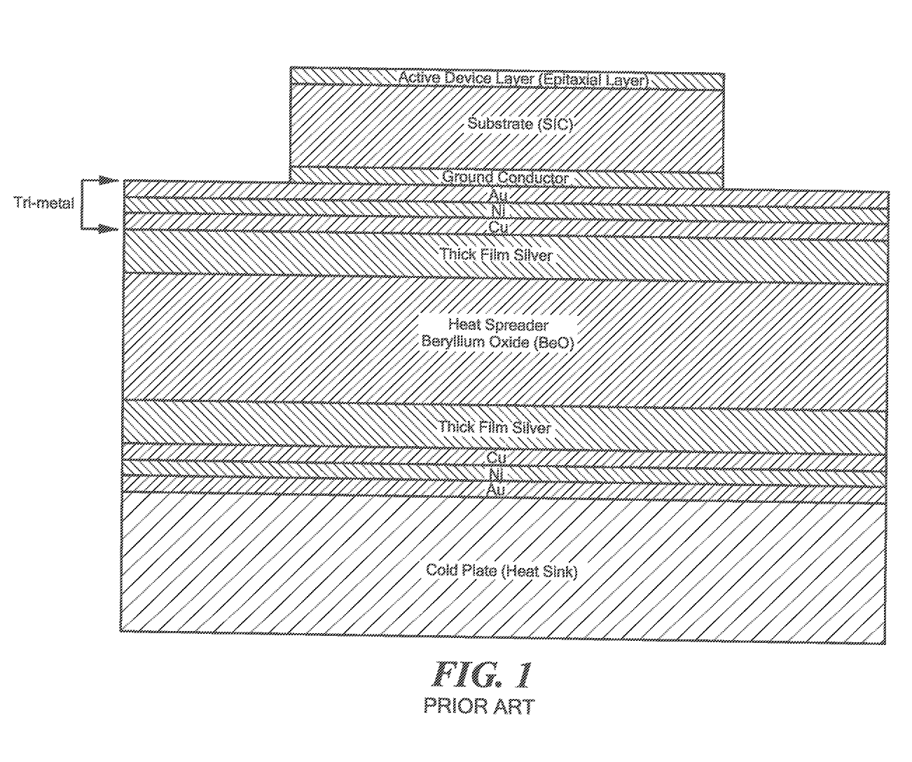

Like reference symbols in the various drawings indicate like elements.

### DETAILED DESCRIPTION

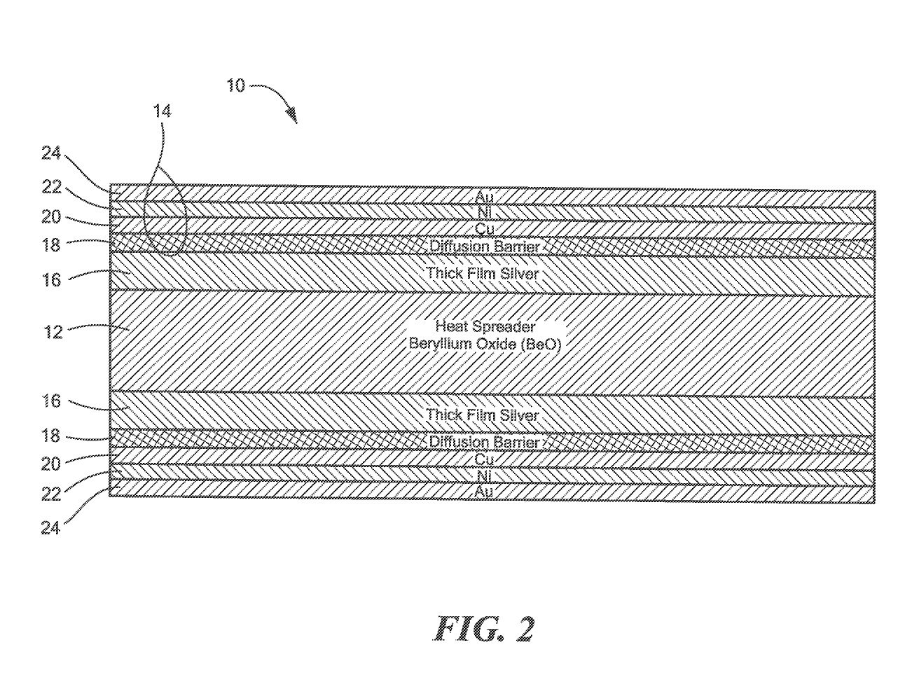

Referring now to FIG. 2 a heat spreader 10 is shown to include a ceramic substrate here for example beryllium oxide (BeO) although other materials may he used such as for example, alumina or aluminum nitride; and a metallization layer structure 14 disposed on at least one surface of the substrate 12, here on the top, horizontal, surface 13, for mounting to a heat source, such as an Monolithic Microwave Integrated Circuit chip, not shown, and the bottom horizontal surface 15, for mounting to a heat sink, not shown.

Here, the a metallization layer structure 14 includes: a thick film layer 16; a diffusion barrier layer 18 on, and in direct contact with the thick film layer 16; a heat conducting layer 20, here copper (Cu) or silver (Ag), disposed on, and in direct contact with, the diffusion barrier layer 18, a layer 22 of nickel (Ni) on the copper or silver layer 20, and a layer 24 of gold, as indicated in FIG. 2, or silver or tin, as mentioned in the example described below, on the layer 22 of nickel. The diffusion barrier layer 18 inhibits material, here silver, in the thick film layer 16 and material, here copper, in the heat conducting layer 20 from diffusing between the thick film layer 16 and the heat conductive layer 20.

Here, for example, the diffusion barrier layer 18 is an autocatalytic deposited layer of Ni (for example, ASTM-B733, type IV, having a thickness in a range of, for example, 50 micro-inches to 300 micro-inches; the layer 20 is here, for example, Cu (Mil-C14550C, class 2, 100 micro inches or greater) thick, the thick film layer 16 is here, a thick film of Ag: having a resistivity in a range, for example, of 1.5 mΩ/sq (milli-ohms per square) to 20 mΩ/sq and a thickness in a range of, for example 10 to 30 micrometers. Other thick films may be used such as, for example, Ag, PdAg, PtPdAg. The layer 22 is here an electrolytic deposited layer of nickel (Ni): AMS-QQ-N-290, class II having a thickness, for example, in a range from 60 micro-inches to 300 micro-inches is formed on the Cu layer 20. Here, the Au layer 24 is Mil-G-45204C type III, grade A, here, for example, having a thickness of 1 to 50 micro-inches thickness; it being understood that the thickness is a function of the solder and the solder process to be used is plated onto the electrolytic deposited layer 22 of Ni.

Here, the thick film layer 16 is stenciled or screen printed and fired onto the top surface 13 and the bottom horizontal surface 15 of the ceramic substrate 12. Next the layer 18 is electroplated onto the surface of the layer 16. Next layers 20, 22 and 24 are sequentially electroplated one on top of the other to form the structure shown in FIG. 2.

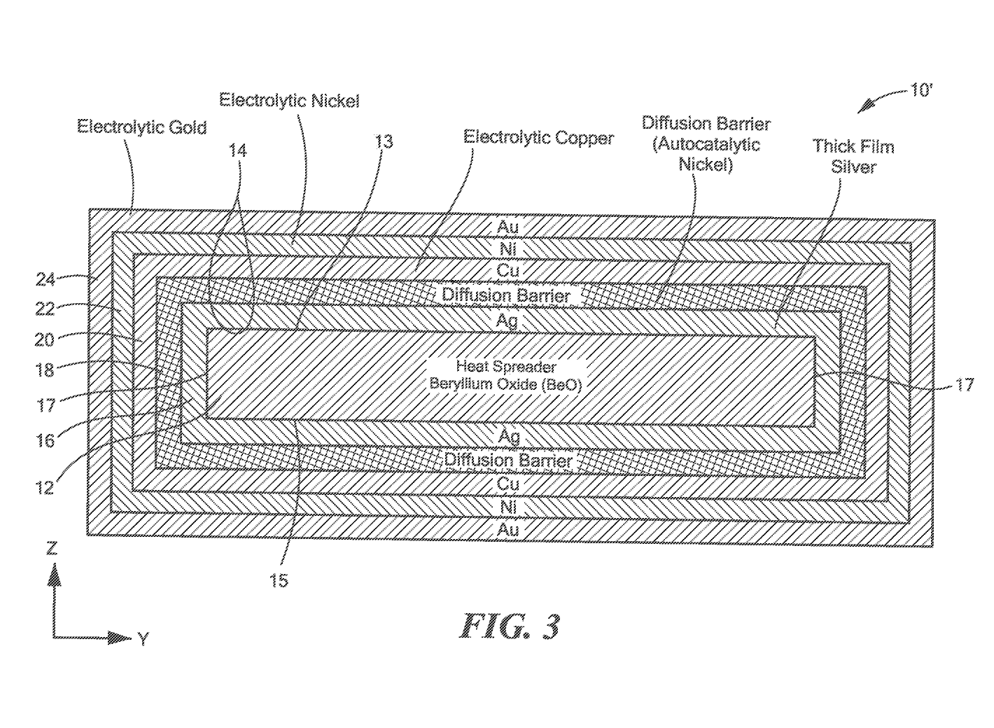

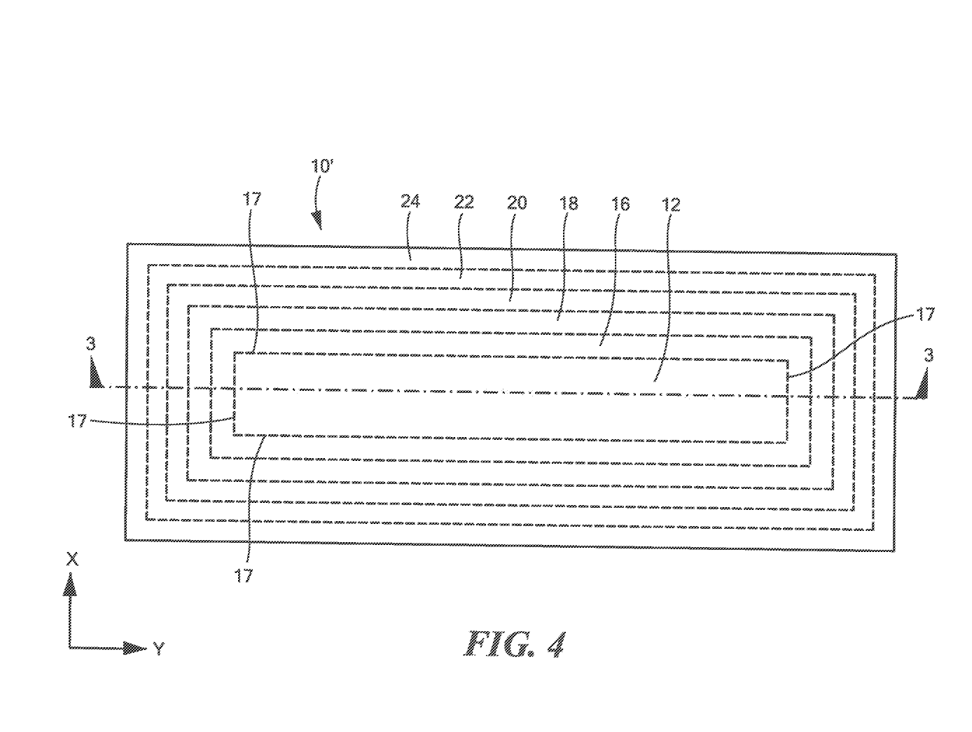

Referring now to FIGS. 3 and 4, a heat spreader 10′ is shown to include a ceramic substrate 12, here for example beryllium oxide (BeO) although other materials may be used such as for example, alumina or aluminum nitride; and a metallization layer structure 14 disposed on at least one surface of the substrate 12, here on the top, horizontal, surface 13, for mounting to a heat source, such as an Monolithic Microwave Integrated Circuit chip, not shown, the bottom horizontal surface 15, for mounting to a heat sink, not shown; and one or more vertical sides, here, for example, all four vertical sides 17, of the ceramic substrate 12. Thus, here the top and bottom surfaces 13, 15 are disposed in the X-Y plane; two of the is vertical sides 17 are disposed in the X-Z plane and the other two vertical sides 17 are disposed in the Y-Z plane.

Here, the metallization layer structure 14 includes: a thick film layer 16; a diffusion barrier layer 18 on, and in direct contact with the thick film layer 16; a heat conducting layer 20, here copper (Cu) or silver (Ag), disposed on, and in direct contact with, the diffusion barrier layer 18, a layer 22 of nickel (Ni) on the copper or silver layer 20, and a layer 24 of gold, as indicated in FIG. 2, or silver or tin, as mentioned in the example described below, on the layer 22 of nickel. The diffusion barrier layer 18 inhibits material, here silver, in the thick film layer 16 and material, here copper, in the heat conducting layer 20 from diffusing between the thick film layer 16 and the heat conductive layer 20.

Here, for example, the diffusion barrier layer 18 is an autocatalytic deposited layer of Ni (for example, ASTM-B733, type IV, having a thickness in a range of, for example, 50 micro-inches to 300 micro-inches; the layer 20 is here, for example, Cu (Mil-C-14550C, class 2, 100 micro inches or greater) thick, the thick film layer 16 is here, a thick film of Ag: having a resistivity in a range, for example, of 1.5 mΩ/sq (milli-ohms per square) to 20 mΩ/sq and a thickness in a range of, for example 10 to 30 micrometers. Other thick films may be used such as fir example, Ag, PdAg, PtPdAg. The layer 22 is here an electrolytic deposited layer of nickel (Ni): AMS-QQ-N-290, class II, having a thickness, for example, in a range from 60 micro-inches to 300 micro inches is formed on the Cu layer 20. Here, the Au layer 24 is Mil-G-45204C type III, grade A, here, for example, having a thickness of 1 to 50 micro-inches thickness; it being understood that the thickness is a function of the solder and the solder process to be used chosen depending on the solder to be used is plated onto the electrolytic deposited layer 22 of Ni.

Here, the thick film layer 16 is stenciled or screen printed and fired onto the top surface 13, the bottom horizontal surface 15, and one or more vertical sides 17, of the ceramic substrate 12. Next the layer 18 is electroplated onto the surface of the layer 16. Next layers 20, 22 and 24 are sequentially electroplated one on top of the other to form the structure shown in FIGS. 2 and 3.

By having a ground plane conductor on the bottom surface of the MMIC in contact with the metallization layer structure on the top surface of the substrate 12, an electrically conductive path, as well as a highly thermally conductive path, is provided around the side or sides of the metalized substrate 12 to the conductive heat sink. With such an arrangement, in high power microwave MMIC device applications will benefit from the full edge wrap from the top, side and bottom of the substrate electrically as well as thermally.

A number of embodiments of the disclosure have been described. Nevertheless, it will be understood that various modifications may be made without departing from the spirit and scope of the disclosure. For example, the ceramic substrate can be diced to final size and held by fixturing to build up the metal stack on four vertical sides. Accordingly, other embodiments are within the scope of the following claims.

What is claimed is:

1. A heat spreader, comprising:
a substrate;
a metallization layer structure disposed on at least one surface of the substrate, comprising:
a thick film layer disposed on the at least one surface of the substrate;
diffusion barrier layer on, and in direct contact with the thick film layer;
a heat conducting layer disposed on, and in direct contact with, the diffusion barrier layer,
wherein the diffusion hairier layer inhibits material in the thick film layer and material in the heat conducting layer from diffusing between the thick film layer and the heat conductive layer.

2. The heat spreader recited in claim 1 wherein the thick film layer comprises silver and wherein the diffusion barrier layer inhibits silver in the thick film layer and the material in the heat conducting layer from diffusing between the thick film layer and the heat conductive layer.

3. The heat spreader recited in claim 1 wherein the heat conductive layer comprises copper and wherein the diffusion barrier layer inhibits material in the thick film layer and the copper in the heat conducting layer from diffusing between the thick film layer and the heat conductive layer.

4. The heat spreader recited in claim 3 wherein the thick film layer comprises silver and wherein the diffusion barrier layer inhibits silver in the thick film layer and the copper in the heat conducting layer from diffusing between the thick film layer and the heat conductive layer.

5. The heat spreader recited in claim 1 wherein the metallization layer structure is disposed on a plurality of sides of the substrate.

6. The heat spreader recited in claim 5 wherein the at least one surface is a horizontal surface and another surface is at least one vertical side of the substrate.

7. The heat spreader recited in claim 5 wherein the metallization layer structure is disposed on top and bottom surface of the substrate.

8. The heat spreader recited in claim 5 wherein the metallization layer structure is disposed on a plurality of sides of the substrate.

9. The heat spreader recited in claim 6 wherein the metallization layer structure is disposed on a plurality of the vertical sides of the substrate.

10. The heat spreader recited in claim 7 wherein the metallization layer structure is disposed on at least one vertical side of the substrate.

11. The heat spreader recited in claim 7 wherein the metallization layer structure is disposed on a plurality of vertical sides of the substrate.

12. The heat spreader recited in claim 1 wherein the substrate is a ceramic substrate.

13. The heat spreader recited in claim 2 wherein the substrate is a ceramic substrate.

14. The heat spreader recited in claim 3 wherein the substrate is a ceramic substrate beryllium oxide.

15. The heat spreader recited in claim 4 wherein the substrate is a ceramic substrate beryllium oxide.

16. The heat spreader recited in claim 5 wherein the substrate is a ceramic substrate beryllium oxide.

17. The heat spreader recited in claim 12 wherein the ceramic substrate is beryllium oxide.

18. The heat spreader recited in claim 13 wherein the ceramic substrate is beryllium oxide.

19. The heat spreader recited in claim 14 wherein the ceramic substrate is beryllium oxide.

20. The heat spreader recited in claim 15 wherein the ceramic substrate is beryllium oxide.
